(19) United States
(12) Patent Application Publication
(10) Pub. No.: US 2009/0093074 A1
(43) Pub. Date: Apr. 9, 2009

(54) Light Emission From Silicon-Based Nanocrystals By Sequential Thermal Annealing Approaches

(76) Inventors: Jae Hyung Yi, Cambridge, MA (US); Luca Dal Negro, Cambridge, MA (US); Lionel C. Kimerling, Concord, MA (US)

Correspondence Address: GOODWIN PROCTER LLP;PATENT ADMINISTRATOR, 53 STATE STREET, EXCHANGE PLACE, BOSTON, MA, 02109-2881, US

(21) Appl. No.: 12/137,224

(22) Filed: Jun. 11, 2008

Related U.S. Application Data
(63) Continuation-in-part of application No. 11/637,405, filed on Dec. 12, 2006, now abandoned.
Application No. 11/637,405 is a continuation-in-part of application No. 11/113,624, filed on Apr. 25, 2005, now Pat. No. 7,407,896.
(60) Provisional application No. 60/565,164, filed on Apr. 23, 2004.
(60) Provisional application No. 60/564,900, filed on Apr. 23, 2004.
(60) Provisional application No. 60/631,041, filed on Nov. 24, 2004.

(51) Int. Cl. H01L 21/28

(52) U.S. Cl. 438/29; 257/E33.061

(57) ABSTRACT

A method for enhancing photoluminescence includes providing a film disposed over a substrate, the film including at least one of a semiconductor and a dielectric material. Light emission may be activated by thermal annealing post growth treatments when thin film layers of SiO₂ and SiNₓ or Si-rich oxide are used. A first annealing step is performed at a first temperature in a processing chamber or annealing furnace; and, thereafter, a second annealing step is performed at a second temperature in the processing chamber or annealing furnace. The second temperature is greater than the first temperature, and the photoluminescence of the film after the second annealing step is greater than the photoluminescence of the film without the first annealing step.

### PRIORITY INFORMATION

The present patent application is a continuation-in-part of and claims the benefit of and priority to both U.S. patent application Ser. No. 11/637,405, filed on Dec. 12, 2006, and U.S. patent application Ser. No. 11/113,624, filed on Apr. 25, 2005, which claims priority under 35 U.S.C. §119 from U.S. Provisional Patent Application Ser. No. 60/565,164, filed on Apr. 23, 2004; from U.S. Provisional Patent Application Ser. No. 60/564,900, filed on Apr. 23, 2004; and from U.S. Provisional Patent Application Ser. No. 60/631,041, filed on Nov. 24, 2004. The entire contents of all of these applications are hereby incorporated by reference in their entireties.

### GOVERNMENT LICENSE RIGHTS

This invention was made with government support under the MIT Office of Sponsored Research Project Number 6894014, sponsored by the National Science Foundation, grant number DMR-0213282. The government has certain rights to this invention.

### FIELD OF THE INVENTION

s invention pertains generally to optical materials, and in particular to light-emitting, silicon-based nanocrystals, light emitting aperiodic photonic structures, and the fabrication thereof.

### BACKGROUND

Conventional multilayer-deposition approaches have produced good quality periodic photonic structures, like Fabry-Perot Microcavities and distributed Bragg mirrors. More challenging is the fabrication of high quality aperiodic structures. An example of such a photonic structure is a deterministic aperiodic structure such as the one generate by a Thue-Morse sequence. This is just an example of aperiodic photonic structures and does not limit the approach we are proposing to this specific choice.

Specifically, an aperiodic structure generated by a Thue-Morse sequence is a structure obtained by the simple inflation rule .σ_{T-M}: A→AB, B→BA. Very recently the authors demonstrated omnidirectional reflectivity in a passive Thue-Morse photonic structure fabricated by a standard sputtering deposition technique. It is known theoretically that aperiodic structures show fractal distribution of sharp band-edge states with resonant transmission and strong field enhancement effect.

However, despite the big potential of aperiodic structures for enhancing light-matter interactions, no such aperiodic structures have been demonstrated combining both strong light-matter interaction and light emission. In fact, the standard materials approaches used to fabricate aperiodic photonic structures are not suited to obtain strong light emission homogeneously from all the layers constituting the structures. In other words, conventional materials used to fabricate aperiodic structures do not provide efficient light emission originating homogeneously from within the photonic structure itself.

Therefore, it is desirable to develop CMOS-compatible light emitting photonic structures that can produce efficient room temperature light emission homogeneously from the inside of photonic structure. Moreover, it is desirable to develop materials that can be used to fabricate aperiodic structures that obtain strong light-matter coupling homogeneously from all the layers constituting the structures.

Silicon (Si) has recently been shown to be a powerful material for integrated optics, modulation, switching, and even lasing. It has not, however, been proven to be an efficient light-emitting material. Light emission in bulk Si originates from a low-probability, phonon-mediated transition that unfavorably competes with fast, non-radiative recombination paths. The lack of efficient light emission in bulk Si has hampered the monolithic integration of electronic and optical devices on mass-produced Si-based chips.

Recent new techniques are providing methods to turn Si into a more efficient light-emitting material. New Si nanostructures have been synthesized that take advantage of quantum confinement to improve light-generation efficiency. Nevertheless, a need exists for further improvement.

### SUMMARY

A process is provided for improved light emission from silicon nanocrystals, a fundamental material system for CMOS-compatible light emitters. The disclosed methods may also be applied to other material systems that utilize a large number of light emitting centers of appropriate sizes. In particular, sequential thermal annealing enables the formation of a high density of silicon nanocrystals (Si-nc), favorable for better light emission and electrical injection, with CMOS-compatible matrices, e.g., Si, SiN, SiON, SiGe, etc.

In an aspect, the invention features a method of fabricating an aperiodic multilayer structure. The method includes depositing a thin film layer of SiO₂ onto a substrate; depositing a thin film layer of SiNₓ upon the layer of SiO₂ to form a structure; and thermally annealing the structure formed by depositing the thin film layer of SiO₂ and the thin film layer of SiNₓ. The thermal annealing may be carried by an initial low temperature annealing process followed by a higher temperature annealing process.

In another aspect, the invention features a coupled aperiodic structure having fractal cavities. The coupled aperiodic structure may include a plurality of aperiodic multilayers, each aperiodic multilayer being constructed of thermally annealed thin film layers of SiO₂ and SiNₓ; and a dielectric spacer positioned between each aperiodic multi layer.

In still another aspect, the invention includes a light emitting device. The light emitting device may include two aperiodic multilayer structures, each aperiodic multilayer structure being constructed of thermally annealed thin film layers of SiO₂ and SiNₓ; and layers of rare earth atoms positioned between each aperiodic multilayer structure.

In another aspect, the invention includes a photonic quasicrystal planar device. The photonic quasicrystal planar device may include a channel waveguide structure with aperiodic etched trenches along a guiding direction, a core of the channel waveguide structure being constructed of thermally annealed SiNₓ; and a low index material formed within the aperiodic etched trenches of the channel waveguide structure.

In another aspect, an embodiment of the invention features a method for enhancing photoluminescence. The method includes providing a film over a substrate, where the film includes at least one of a semiconductor or a dielectric material. A first annealing step is performed at a first temperature in a processing chamber or annealing furnace. Thereafter, a second annealing step is performed at a second temperature in the processing chamber or annealing furnace. The second temperature is greater than the first temperature, and a second photoluminescence of the film after the second annealing step is greater than an initial photoluminescence of the film before the first annealing step.

One or more of the following features may be included. The substrate may remain in the processing chamber or annealing furnace between the first and second annealing steps. The substrate may be removed from the processing chamber or annealing furnace after the first step, and re-inserted into the processing chamber or furnace for the second step after a temperature of the processing chamber or annealing furnace is stabilized at the second temperature. The film may include silicon. The dielectric material may include or consist essentially of, e.g., SiO₂, Si₃N₄, Si-rich silicon oxide, Si-rich silicon nitride, and/or Si-rich oxynitride. The first temperature may be selected from a range of 300° C. to 1300° C., preferably 400° C. to 1250° C., and more preferably 500° C. to 1200° C. The film thickness may be selected from a range of 0.1 μm to 5 μm.

### BRIEF DESCRIPTION OF FIGURES

The present invention may take form in various components and arrangements of components, and in various steps and arrangements of steps. In the drawings, like reference numbering has been used throughout to designate identical or equivalent elements. It is also noted that the various drawings illustrating the present invention may not have been drawn to scale and that certain regions may have been purposely drawn disproportionately so that the features and concepts of the present invention could be properly illustrated. The drawings are only for purposes of illustrating a preferred embodiment or embodiments and are not to be construed as limiting the present invention, wherein:

FIG. 1 is a cross-sectional view of a structure that may be employed in an embodiment of the invention;

FIGS. 2, 4a, and 4b are graphs representing annealing temperature profiles in accordance with embodiments of the invention;

FIGS. 3a, 3b, and 5 are photoluminescence spectra of materials annealed in accordance with embodiments of the invention;

FIG. 6 is a schematic diagram illustrating an aspect of the invention;

FIG. 7 graphically illustrates transmission characteristics of Thue-Morse photonic structures constructed in accordance with the concepts of the present invention;

FIG. 8 graphically illustrates a relationship between emission and annealing temperatures in accordance with the concepts of the present invention;

FIGS. 9 and 10 graphically illustrate transmission characteristics of multi-interfaces structures after annealing in accordance with the concepts of the present invention;

FIG. 11 graphically illustrates light emission enhancement at the resonant states in accordance with the concepts of the present invention;

FIG. 12 is a schematic diagram of a one-dimensional aperiodic structure in accordance with the concepts of the present invention;

FIG. 13 illustrates various vertical aperiodic structures in accordance with the concepts of the present invention;

FIG. 14 illustrates a vertical aperiodic structure with an embedded emitter in accordance with the concepts of the present invention;

FIG. 15 illustrates coupled aperiodic structure in accordance with the concepts of the present invention;

FIG. 16 illustrates an aperiodic cladding structure in accordance with the concepts of the present invention; and

FIG. 17 illustrates a planar aperiodic waveguide in accordance with the concepts of the present invention.

### DETAILED DESCRIPTION

Features of the present invention are described in connection with preferred embodiments; however, there is no intent to limit the present invention to the embodiments described herein. On the contrary, the intent is to cover all alternatives, modifications, and equivalents as may be included within the spirit and scope of the present invention as defined by the appended claims.

Embodiments of the present invention may include light emitting optical devices characterized by aperiodic order and strong light-matter interaction. The application fields are integrated non-linear optics, low threshold optical amplifiers, on-chip optical sensors, optical switches, and all optical delay lines based on strong light dispersion in aperiodic photonic crystals structures.

More specifically, embodiments of the present invention may include deterministic aperiodic photonic materials (photonic quasicrystals) and structures, where critical and localized light states can trap light waves of several frequency simultaneously (multi-frequency photon localization), and the presence of narrow resonant states with high quality factors (high Q states), leads to dramatic enhancement effects in the electric field modes and to strong light dispersion effects with respect to regular photonic crystals structures.

Photonic quasicrystals are dielectric materials where the refractive index fluctuates without spatial periodicity, though the index profile is generated according to simple deterministic rules (such as the Fibonacci sequence: Fⱼ₊₁=Fⱼ+Fⱼ₋₁). This class of perfectly ordered materials realizes an intermediate regime of geometrical organization between random structures and periodic ones.

Analogously to photonic band-gap materials, photonic quasicrystals can be realized by stacking together layers of different dielectric materials with thicknesses comparable to the wavelength of light. Moreover, photonic quasicrystals provide extremely complex fractal spectra, high Q resonance transmission states, localized and fractal photon states with sizeable field enhancement, and anomalous light diffusion. Lastly, photonic quasicrystals can effectively enable strong group velocity reduction (slow photons); strong light-matter interaction; light emission enhancement; gain enhancement; and/or nonlinear optical properties enhancement. As such, photonic quasicrystals can enhance the performance of light emitting devices, integrated non-linear optics, low threshold optical amplifiers, on chip optical sensors, optical switches, ultrashort optical pulse compression elements, and optical delay lines.

To fabricate the light emitting photonic, periodic photonic, and non-periodic photonic structures described here, a fabrication process utilizes thin film deposition of dielectrics followed by thermal annealing treatments that activates efficient room temperature light emission. In one embodiment of the present invention, the thin film dielectrics may be SiO₂ and Si-rich nitride (SiNₓ).

The fabrication process may include deposition on transparent fused silica substrates through plasma enhanced chemical vapor deposition. However, several other thin-films fabrication procedures can be utilized.

In a specific example, silicon nitride layers are deposited using SiH₄ and N₂ as precursors while oxide layers are deposited using SiH₄ and N₂O. The substrate temperature during deposition is about 400° C. In order to maximize the effect of light scattering, the thickness d_{A,B} of the two materials, SiNₓ (layer A) and SiO₂ (layer B), has been chosen to satisfy the Bragg condition, d_{A}n_{A}=d_{B}n_{B}=λₒ/4, where n_{A} (2.23) and n_{B} (1.45) are the respective refractive indices and λₒ=1.65 μm.

Within a fully VLSI-CMOS compatible annealing window, the present invention utilizes a post-deposition annealing treatment in N₂ atmosphere that produces active devices with efficient light emission from the layers of the photonic structures. In addition, the present invention yields little absorption losses in the visible range and intense broad band photoluminescence.

It is noted that the luminescence band can further be tuned by deposition of oxynitride (SiONₓ) thin films with variable stoichiometry.

Furthermore, it is noted that low temperature pre-annealing processes followed by higher temperature thermal annealing treatments in forming gas atmosphere can be utilized to control the spectral width of the emission band.

In one fabrication embodiment, various annealing treatments, ranging from 400° C. up to 1300° C. enable the fabrication of photonic structures that have a greater degree of flexibility and light emission control than structures produced by conventional fabrication processes. It is noted that the annealing time is determined according to the structure composition wherein the annealing time ranges from 1 minute to several hours. The thermal annealing post growth process activates the light emission homogeneously from the layers of the structures (interfaces).

Utilizing the fabrication process of the present invention, the aperiodic Thue-Morse photonic structures demonstrate interface quality comparable with conventionally fabricated periodic structures, allowing for the observation of complex transmission spectra with large field enhancement effects and light dispersion.

Sequential thermal annealing treatments are employed to improve the optical emission properties of Si-based materials, and to tune Si-cluster size and size distribution. As used herein, “sequential thermal annealing” refers to any combination of thermal annealing steps that includes low-temperature annealing and high-temperature annealing. “Low temperature” signifies any temperature lower than that of the main or primary annealing step.

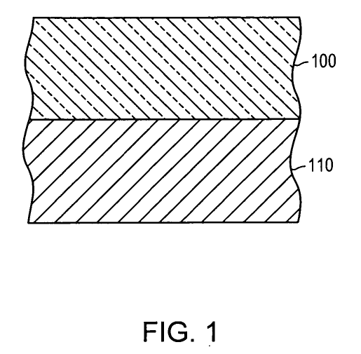

Referring to FIG. 1, a film 100 is formed over a substrate 110. The film 100 may include or consist essentially of a semiconductor material or a dielectric material. Examples of suitable semiconductor materials are group IV elements or compounds, such as Si, Ge, SiGe, and SiC; a III-V compound, such as GaAs, InGaAs, GaInP, GaN, InGaN, AlGaN, and InP; and/or a II-VI compound, such as CdTe and ZnSe. Examples of suitable dielectric material include silicon dioxide (SiO₂), silicon nitride (Si₃N₄), Si-rich oxide (SRO), Si-rich nitride (SRN), and Si-rich oxynitride (SRON). These materials offer the advantages of efficient photoluminescence, fast recombination time, materials reliability, and the strong energy sensitization of rare earth atoms (Er in particular). Nitride and oxide materials may be doped with Er and other rare earth elements, such as Yb, Nd, Pr, Tm, Ho, etc., to extend the emission range in the near-infrared region.

The film 100 may have a thickness selected from a range of, e.g., 0.1 μm to 5 μm (in one particular embodiment, the thickness is 1 μm).

The film 100 may be formed by, e.g., magnetron sputtering, plasma enhanced chemical vapor deposition (PECVD), low-pressure chemical vapor deposition (LPCVD), or other suitable techniques. For example, SiO₂ may be formed by sputtering a silicon target with argon and oxygen. A silicon-rich oxide may be formed by sputtering Si and an SiO₂ targets. A silicon-rich oxide may also be grown by, e.g., PECVD or LPCVD, or may be formed by implanting Si into a SiO₂ film and annealing at a high temperature.

The substrate 110 may be a semiconductor substrate, including or consisting essentially of a group IV element or compound, such as Si, Ge, SiGe, and SiC; a III-V compound, such as GaAs, InGaAs, GaInP, GaN, InGaN, AlGaN, and InP; and/or a II-VI compound, such as CdTe and ZnSe. Examples of the semiconductor substrate include bulk Si and silicon-on-insulator (SOI).

Annealing steps following deposition cause formation of Si-nc inside the film. A high density of Si-nc, e.g., in the range of approximately 10¹⁵ to 10¹⁹/cm³, with an appropriate size, e.g., having a diameter in the range of about 1 to 10 nm, is highly preferred for good light emission from these material systems.

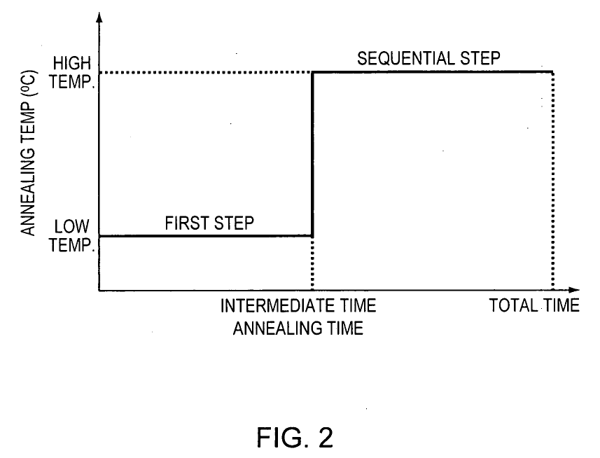

Referring to FIG. 2, a typical sequential annealing profile in accordance with an embodiment of the invention, with a low-temperature anneal, leads to the formation of a large number of Si-nc. However, if only a low temperature annealing step is performed, appropriate Si-nc sizes may not be achieved due to a lack of energy for growth. Therefore, materials annealed only at low temperature typically do not provide good light emission. On the other hand, annealing only at a high temperature, e.g., at 1200° C., may lead to the formation of large Si-nc, but the number of Si-nc may be limited due to reduced nucleation at high temperatures. In accordance with an embodiment of the invention, therefore, sequential thermal annealing enables the formation of Si-nc having an average size that is sufficiently small to utilize quantum confinement effects for better light emission. Moreover, sequential thermal annealing as described herein also enables the creation of a sufficient significantly greater number of emitting centers.

In an embodiment of the invention, a first annealing step at a first temperature is performed in a processing chamber or annealing furnace. The first temperature may range from, e.g., 300° C. to 1300° C., preferably from 400° C. to 1250° C., and most preferably from 500° C. to 1200° C. The substrate and overlying film are subsequently subjected to a second annealing step in the same processing chamber or annealing furnace. The second annealing step is performed at a second temperature that is higher than the first temperature. The second temperature may range from, e.g., 300° C. to 1300° C., preferably from 400° C. to 1250° C., and most preferably from 500° C. to 1200° C. The photoluminescence of the film after the second annealing step is greater than the photoluminescence before the first annealing step.

The substrate may remain in the processing chamber or annealing furnace between the first and second annealing steps. Alternatively, the substrate may be removed from the processing chamber or annealing furnace after the first step, and re-inserted therein for the second step after the temperature of the processing chamber or annealing furnace is stabilized at the second temperature.

The effects of sequential thermal annealing steps on light emission were investigated, with the goal of increasing the density of Si-nc and to increase their emission intensity. Specifically, the role of sequential thermal annealing steps on the inducement of Si-nc nucleation and activation of efficient light emission was investigated in a controlled nitrogen atmosphere. After thermal annealing, strong near infrared (700-900 nm) light emission at room temperature under optical pumping was observed.

Room-temperature photoluminescence experiments were preformed by using a 488 nm Ar pump laser and a liquid nitrogen cooled InGaAs photomultiplier tube.

Low temperature pre-annealing treatment of reactively sputtered substoichiometric oxide (e.g., a SiOₓ matrix) films was performed to induce the formation of a large number of small Si clusters that can act as initial nucleation sites for a subsequent nucleation induced by a higher temperature treatment.

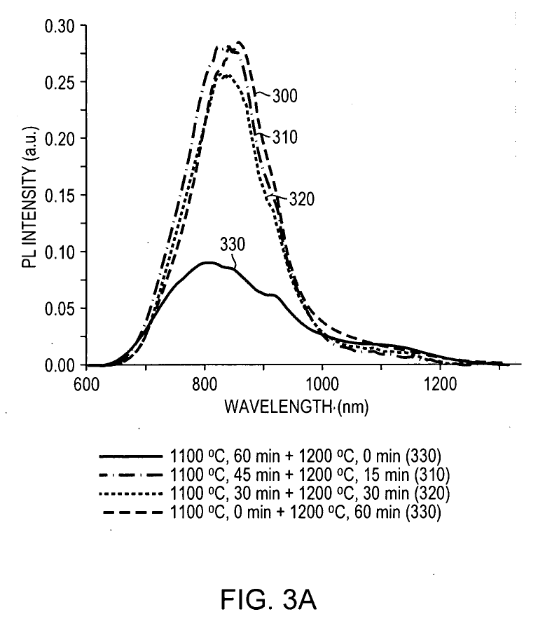

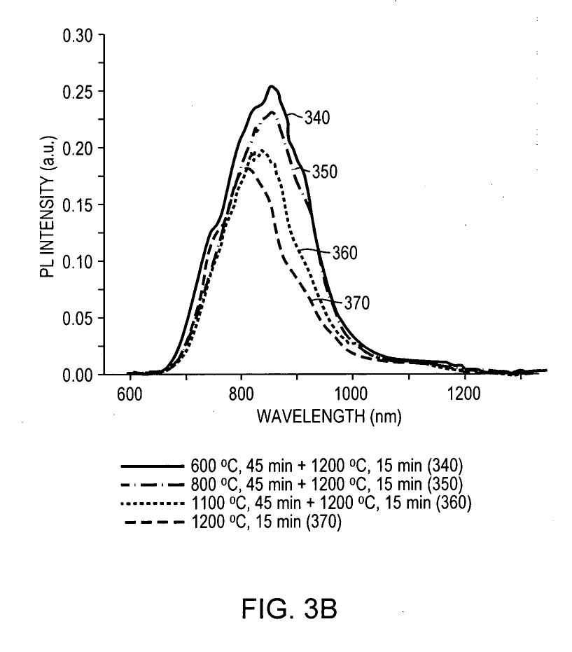

All of the experimental annealing treatments were performed in a controlled nitrogen atmosphere. Typical annealing temperatures ranged from 600° C. to 1200° C., and the total annealing time was kept fixed to 1 hour. FIG. 3(a) illustrates room-temperature photoluminescence spectra for structures subjected to a first annealing step for a duration of 15, 30, or 45 minutes at a fixed temperature of 1100° C. in an annealing furnace, and then subjected to a second annealing step at 1200° C. in the same annealing furnace for a duration selected such that the total annealing time was 1 hour (i.e., 45, 30, or 15 minutes, respectively). The substrate remained in the annealing furnace between the first and second annealing steps. In some embodiments, the substrate may be removed from a processing chamber or annealing furnace after the first annealing step, and re-inserted into the processing chamber or furnace for the second step after a temperature of the processing chamber or furnace is stabilized at the second temperature.

As shown in FIG. 3(a), the light-emission intensity is highest in samples annealed for either 1 hour at 1200° C. (curve 300), or for a shorter annealing time at the same 1200° C. temperature, but following a pre-annealing step at 1100° C. (curve 310). A similar light emission intensity appears to have been achieved at a sequential anneal of 30 minutes at 1100° C. and 30 minutes at 1200° C. (curve 320). A 1 hour anneal solely at 1100° C. yields the poorest light emission intensity (curve 330). This evidence strongly supports the idea that a pre-annealing step performed at a lower temperature can drastically influence the Si-nc nucleation process.

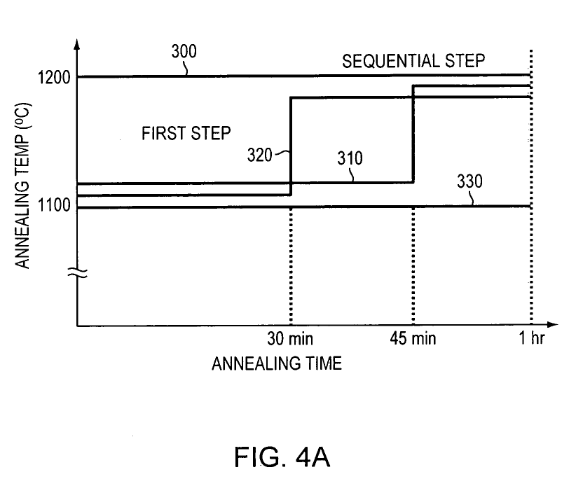

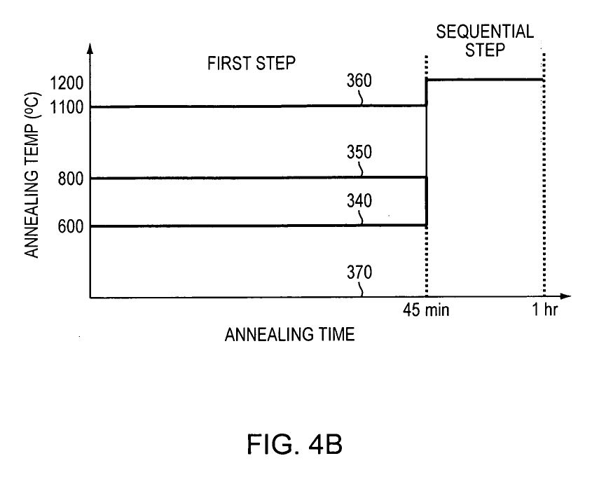

FIG. 3(b) illustrates the results of a more detailed investigation of the influence of the low temperature pre-annealing steps. Here, a pre-anneal was performed for 45 minutes at different temperatures between 600° C. and 1100° C., i.e., at 600° C. (curve 340), 800° C. (curve 350), and 1100° C. (curve 360), and no pre-anneal (curve 370), and a post-anneal was performed for 15 minutes at a fixed temperature of 1200° C. The annealing temperature profiles are illustrated in FIGS. 4a and 4b. As indicated in the figure, the lower the temperature of the first anneal, the higher the final photoluminescence intensity will be.

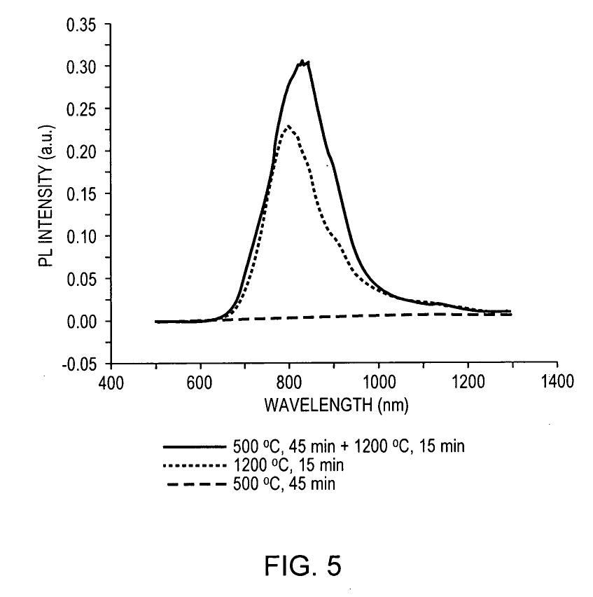

Referring to FIG. 5, the effect of sequential annealing is clearly demonstrated by enhancement of light emission from Si-nc. A comparison was made between samples (i) annealed at only at 500° C. for 45 minutes, (ii) annealed at 500° C. for 45 minutes combined with an anneal at 1200° C. for 15 minutes, and (iii) annealed only at 1200° C. for 15 minutes. Annealing at 500° C. did not have a perceivable effect on the PL intensity of a sample. Moreover, even though PL intensity greatly improved by annealing at 1200° C., the PL intensity of a sample annealed at only 1200° C. is much smaller than that of a sequentially annealed sample.

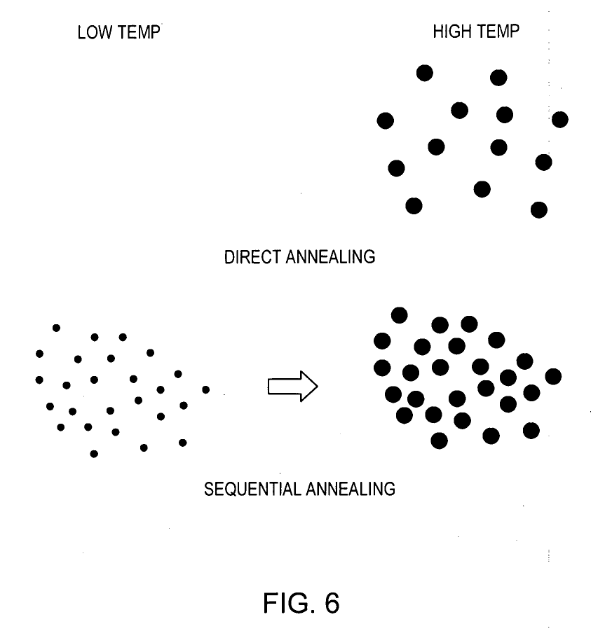

FIGS. 6a and 6b illustrate the likely basis for the improvement of light emission by sequential annealing. Without sequential annealing (see FIG. 6a), the density of light emitters in a film (e.g., Si-nc) is much smaller than that of sequentially annealed film (see FIG. 6b). Embodiments of the invention allow the enhanced nucleation of light emitters in materials such as SiO₂, Si₃N₄, Si-rich silicon oxide, Si-rich silicon nitride, and Si-rich oxynitride, and the improvement of light emission performances by direct control of the initial nucleation site density.

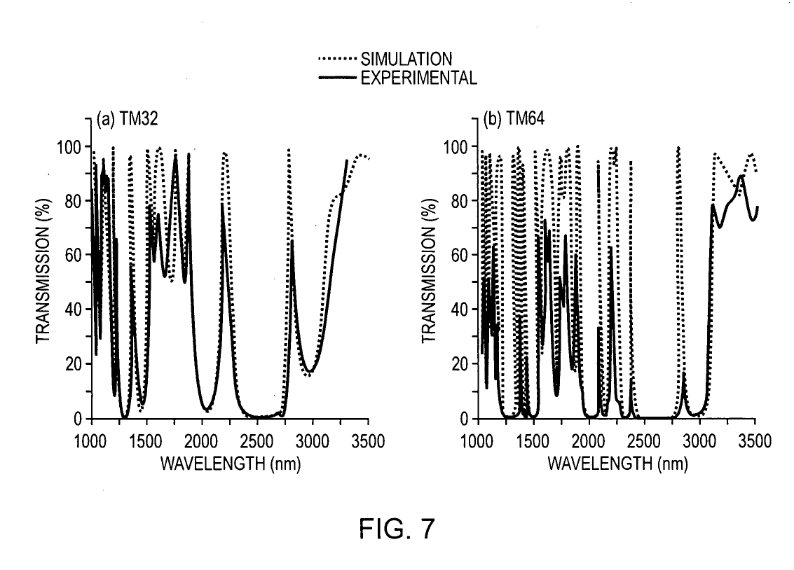

An example of the realized improvement in absorption loss by aperiodic Thue-Morse photonic structures fabricated by the concepts of the present invention is illustrated in FIG. 7. More specifically, FIG. 7 shows the measured optical transmission spectra versus wavelength for a 32 layers photonic Thue-Morse structure fabricated by the concepts of the present invention and for a 64 layers photonic Thue-Morse structure fabricated by the concepts of the present invention.

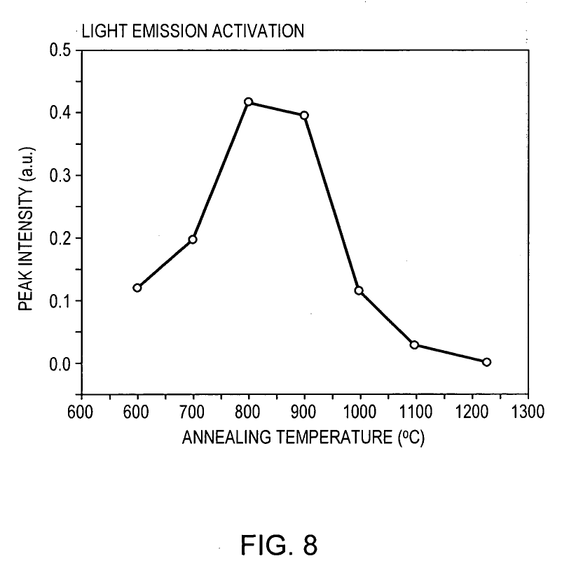

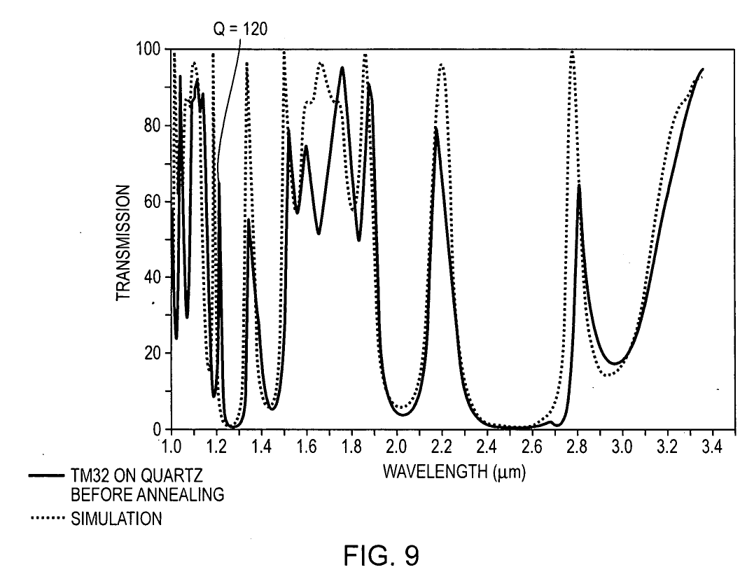

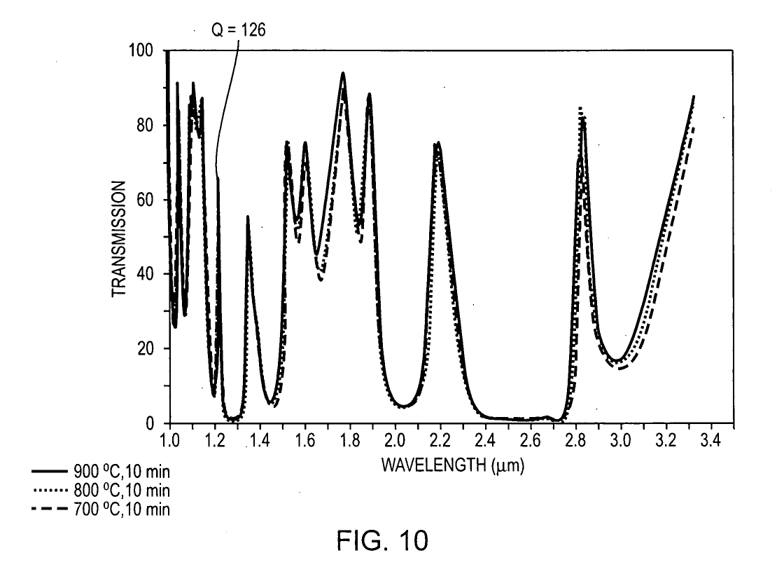

In another example of the fabrication process of the present invention, the deposited thin film dielectrics are thermal annealed, in order to activate broad band light emission from the Si-rich nitride layers. From this thermal annealing treatment, a broad emission band originating from the SiO₂/SiNₓ interfaces can be realized, as illustrated in FIG. 8. However, it is noted that SiO₂/SiNₓ multi-interfaces structures are resistant to the annealing treatments that activate the light emission from the structures, as demonstrated in FIGS. 9 and 10 and the thermal annealing steps are not compromising the photonic properties of the structures.

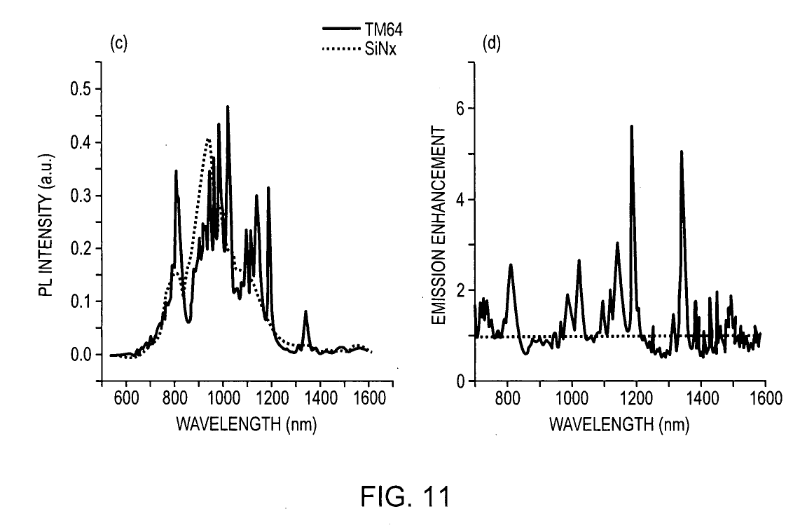

The advantage of fabricating aperiodic photonic structures utilizing the concepts of the present invention is clearly shown in FIG. 11 where the broad light emission spectrum originating from the an homogeneous SiNₓ dielectric layer can be significantly modified and enhanced at the resonant states induced by the geometrical complexity of the aperiodic Thue-Morse structure.

More specifically, as illustrated in FIG. 11, a Thue-Morse structure fabricated utilizing the processes of the present invention can resonantly enhance the light emission efficiency of the material at several wavelengths simultaneously. It is noted that the critical light states characteristic of the Thue-Morse structure may yield an emission enhancement of approximately a factor of 6.

Moreover, it is noted that the utilization of SiNₓ as a high refractive index and a broad band light emitting material enables effective transfer of the excitation to rare earth atoms (for instance erbium) through energy coupling mechanisms. The emission mechanism relies on the formation of nitrogen passivated small silicon clusters dispersed in the embedding Si₃N₄ dielectric host, in close analogy with Si/SiO₂ superlattice systems. In other words, the inclusion of rare earth ions within the nitride or oxynitride structures fabricated by the processes of the present invention produces light emitting photonic structures characterized by efficient near infrared emission with a greater degree of structural flexibility.

On the other hand, the broad photoluminescence band in the multi-interface structures fabricated by the processes of the present invention provide an ideal candidate for efficient energy coupling effects with different rare earth atoms (Pd, Yb, etc) incorporated within the layers, and allows a wider emission tuneability range.

As noted above, the fabrication process of the present invention can be utilized to realize different aperiodic light emitting photonic structures schemes. The Thue-Morse generation rule is just one example of a deterministic prescription that generates a non-periodic layer sequence.

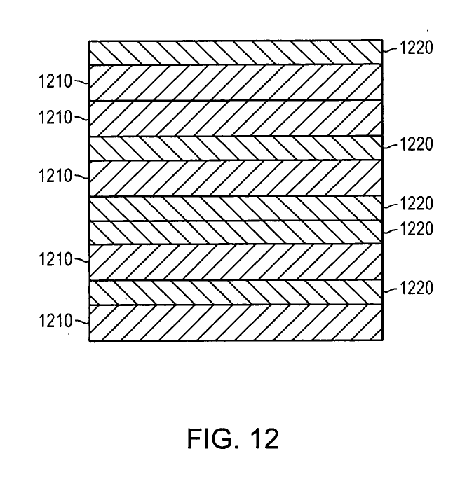

FIG. 12 illustrates an example of photonic structure by the fabrication process of the present invention. As illustrated in FIG. 12, an aperiodic one-dimensional structure includes a stack of two different layers according to aperiodic sequences; for example, Rudin-Shapiro or Thue-Morse structures. In this structure, the layer 1210 is preferably SiOₓ. Moreover, the layer 1220 is preferably SiNₓ. This layer may also be SiONₓ or SiₓGe₁₋ₓ.

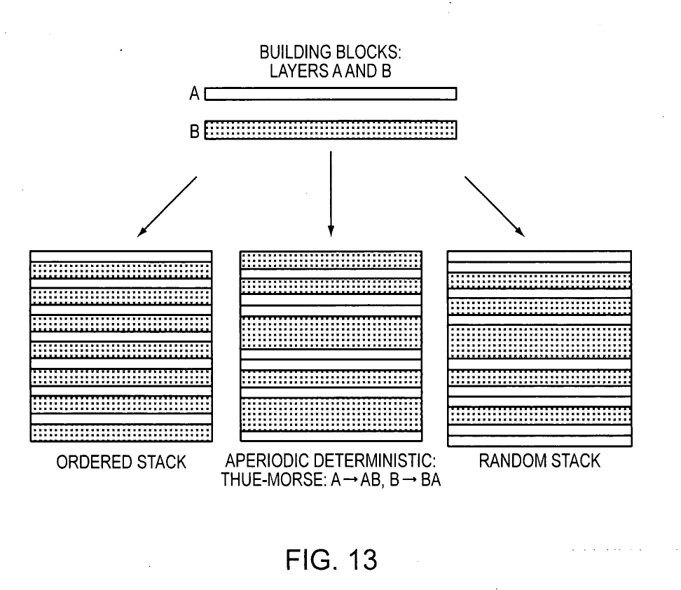

FIG. 13 illustrates various vertical aperiodic structures that can be fabricated by the process of the present invention wherein layer A is preferably SiOₓ, and layer B is preferably SiNₓ or may also be SiONₓ or SiₓGe₁₋ₓ. The various structures include an ordered stack, an aperiodic deterministic stack, and a random stack.

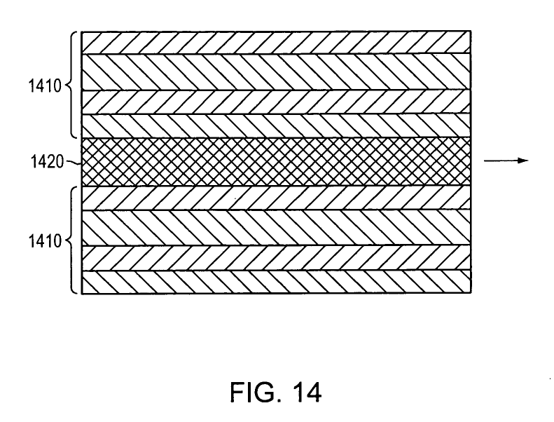

Another example, of photonic structure fabricated by the process of the present invention is illustrated in FIG. 14. As illustrated in FIG. 14, an active structure can be realized by fabricating aperiodic multilayers 1410 of Si-rich nitride (SiNₓ) and Si-rich oxide (SiOₓ). Between the aperiodic multilayers 1410 of Si-rich nitride (SiNₓ) and Si-rich oxide (SiOₓ), a layer 1420 of rare earth elements, such as Er atoms, are fabricated. This layer provides an extra active guiding layer for the emission of near infra red light around 1.55 μm. Layer 1420 may also be a layer of silicon nanocrystals obtained as a result of our annealing process.

It is noted that the energy transfer phenomena from Si-rich oxide and Si-rich nitride can be effective to enhance simultaneously the Er light emission. The combination of these light emitting materials with the strong mode localization effects occurring in photonic aperiodic dielectrics like Rudin-Shapiro and Thue-Morse structures lead to enhanced light-matter coupling effects leading to high excitation efficiencies for rare earth atoms.

It is noted that aperiodic and quasi-periodic luminescent photonic structures characterized by strong light-matter coupling and enhancements effects can be realized by the fabrication process of the present invention. As such, both linear (absorption, emission) and non-linear processes (second harmonic generation, third harmonic processes, light modulation) in the structures can be enhanced as a result of the strong electric field enhancement effects and density of optical modes modifications.

In particular, Thue-Morse and Rudin-Shapiro aperiodic photonic structures can be realized by layer deposition in order to achieve efficient light emission and eventually mirrorless light amplification (fractal laser) behaviour within an enhanced light-matter coupling regime.

It is further noted that light emission at 1.55 μm can be enhanced by Er doping in the SiOₓ and SiNₓ layers of the photonic structures. Deposition methods as Plasma Enhanced Chemical Vapor Deposition and RF magnetron sputtering can be utilized. In addition, based on the aperiodic photonic crystal approach described above, both passive (non-light emitting) and active (light emitting) structures can be realized. The passive device may consist of aperiodically arranged dielectric layers of Si, Si₃N₄, and SiO₂ layers.

As noted above with respect to FIG. 12, fabricated photonic quasicrystal devices are obtained by alternating high refractive index materials like Si, Ge, SiₓGe₁₋ₓ, Si₃N₄, and SiO₂ layers using standard CMOS-compatible deposition techniques like sputtering and chemical vapor deposition. The different layers are assumed to satisfy the Bragg condition (n₁d₁=n₂d₂=λₒ/4) around the working wavelength λ₀=1.55 μm.

It is noted that multi-frequency light emitting devices can be realized using the strongly localized light states in aperiodic multilayer structures (Thue-Morse and Rudin-Shapiro). These laser devices can operate at different frequencies corresponding to closely spaced, localized states. The underlying fractal behaviour of the transmission spectra can provide an integrated light source operating at multiple frequencies.

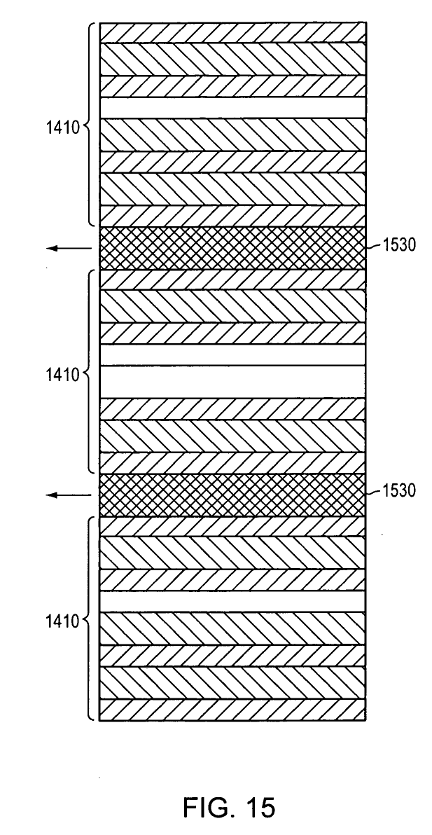

In a further embodiment, the fabrication process can be utilized to couple together sequentially these structures through a dielectric spacer, as illustrated in FIG. 15. FIG. 15 illustrates a coupled aperiodic structure having aperiodic multilayers 1410 separated by dielectric spacers 1530. This structure, as illustrated in FIG. 15, enhances the mode localization (resonant enhancement of the mode density). Moreover, the structure, as illustrated in FIG. 15, realizes fractal cavities that can be used as mirrorless light amplifiers and laser devices operating at multiple wavelengths. It is noted that the aperiodic multilayers are coupled together through dielectric spacer layers.

It is noted that the strong mode coupling in these fractal coupled cavities enable the realization of THz signal modulators operating at the beating frequency of adjacent localized modes simultaneously excited by the internally generated light.

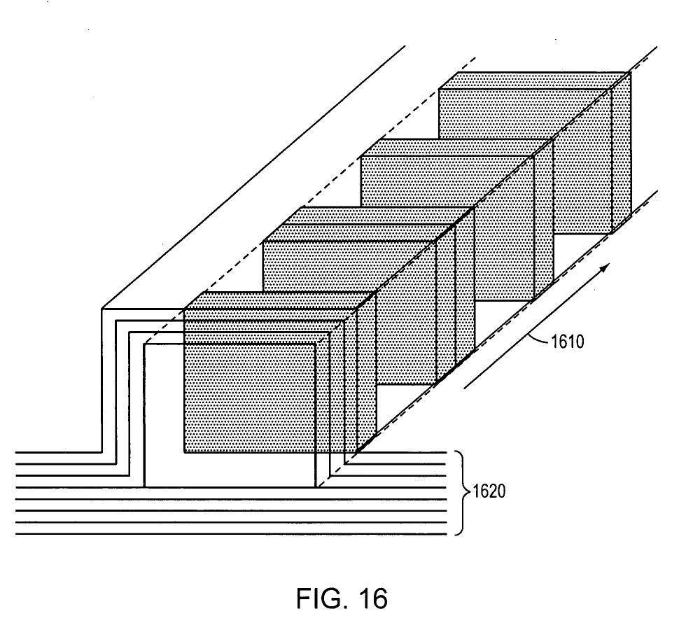

It is further noted that by embedding light emitting materials (Er, silicon nanocrystals) in the SiO₂ core of a waveguide structures with photonic quasicrystal 1610 within cladding layers 1620, as illustrated in FIG. 16, the intrinsic scattering losses introduced by the active inhomogeneous media (like quantum dots) can be reduced and light amplification at reduced pumping threshold can be achieved. The effect of the large photonic bandgaps in aperiodic photonic structures inhibit out of core scattering losses and strongly favor bidirectional mode amplification if an optically active medium is introduced in the low index core region.

It is noted that the present invention provides the possibility of demonstrating a light emitting device that profits from strong light-matter interaction in aperiodic material structures. The light emitting device can be realized by a proper choice of light emitting materials where light emission is activated through thermal annealing steps of the aperiodic structure. In particular, thermally annealed multilayers of SiO₂ and SiNₓ, can be used or, additionally, infrared emitting rare earth atoms can be incorporated at specific locations inside the of SiO₂ layers of the aperiodic structures.

It is also noted that optical delay lines can be realized by using the strong localized light field inside aperiodic structures based on the strongly suppressed group velocity at the localized modes. On the other hand, strong group velocity dispersion in aperiodic structures can be utilized to implement ultrafast optical pulse compression elements.

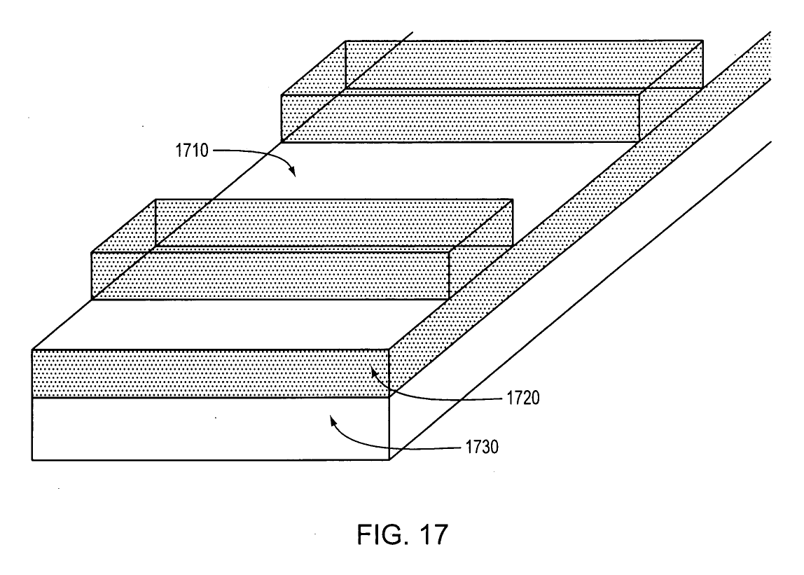

Another device that can be realized by the fabrication process of the present invention is a planar aperiodic waveguide as illustrated in FIG. 17. As illustrated in FIG. 17, a photonic quasicrystal planar device is realized by etching quasiperiodic low index material trenches 1710 in high index contrast material or channel waveguide structures 1720 formed on a substrate 1730. The low index material may be air, SiO₂, polymers, and/or liquid crystals. The planar aperiodic waveguide of FIG. 17 enables an extremely large light-matter interaction length within CMOS compatible planar technology.

As noted above, a photonic quasicrystal distributed grating air trench planar waveguide realizes integrated multi-frequency filters and multi wavelength light emitting components. In addition, photonic quasicrystal distributed SiO₂ trench grating realizes an integrated multi-frequency waveguide amplifier. The active medium (Er, silicon nanocrystals, ILL-V materials, dye molecules, etc.) is embedded inside the SiO₂ trenches.

Lastly, polymers, liquid crystals, or other optically active materials can be used to fill the air trenches to vary the refractive index contrast of the structure realizing a tuneability of both the gap and the localized states that can be used for sensors and optical active devices integrated in a waveguide. This structure can be obtained by standard lithographic and etching CMOS processing and can be readily integrated on a planar silicon platform. The advantages of the planar aperiodically trenched waveguides rely in the huge light-matter interaction length with respect to vertical multilayers structures.

In summary, the fabrication process of the present invention realizes photonic quasicrystal devices that provide strong group velocity reduction (slow photons), strong light-matter interaction, light emission enhancement, gain enhancement, and/or nonlinear optical properties enhancement. Moreover, a viable and flexible solution for the realization of strong photonic enhancement and localization effects in high quality periodic and aperiodic photonic structures emitting at 1.55 μm is realized by the concepts of the present invention.

The fabrication process of the present invention is entirely compatible with CMOS processes; utilizes high index (refractive index ranging from 1.6 to 2.3) material to allow flexible design of high confinements photoriic devices with strong structural stability with respect to annealing treatments; realizes broad band light emission by allowing resonant coupling with rare earth atoms and other infrared emitting quantum dots; realizes better electrical conduction properties with respect to SiO₂ systems; enables high transparency (low pumping and modal losses) in the visible range; and/or enables structural stability by allowing the realization of good quality light emitting complex photonic structures and photonic crystals structures.

The invention may be embodied in other specific forms without departing from the spirit or essential characteristics thereof. The foregoing embodiments are therefore to be considered in all respects illustrative of the invention described herein. Various features and elements of the different embodiments can be used in different combinations and permutations, as will be apparent to those skilled in the art. The scope of the invention is thus indicated by the appended claims rather than by the foregoing description, and all changes which come within the meaning and range of equivalency of the claims are therefore intended to be embraced herein.

What is claimed is:

1. A method for enhancing photoluminescence, the method comprising the steps of:
providing a film over a substrate, the film including at least one of a semiconductor or a dielectric material;
performing a first annealing step at a first temperature in a processing chamber or annealing furnace; and
thereafter, performing a second annealing step at a second temperature in the processing chamber or annealing furnace,
wherein the second temperature is greater than the first temperature, and a second photoluminescence of the film after the second annealing step is greater than an initial photoluminescence of the film before the first annealing step.

2. The method of claim 1, wherein the substrate remains in the processing chamber or annealing furnace between the first and second annealing steps.

3. The method of claim 1, wherein the substrate is removed from the processing chamber or annealing furnace after the first step, and re-inserted into the processing chamber or furnace for the second step after a temperature of the processing chamber or annealing furnace is stabilized at the second temperature.

4. The method of claim 1, wherein the film comprises silicon.

5. The method of claim 4, wherein the dielectric material comprises at least one of SiO₂, Si₃N₄, Si-rich silicon oxide, Si-rich silicon nitride, or Si-rich oxynitride.

6. The method of claim 5, wherein the dielectric material comprises at least one of SiO₂ and Si-rich silicon oxide, and the first temperature is selected from a range of 300° C. to 1300° C.

7. The method of claim 6, wherein the first temperature is selected from a range of 400° C. to 1250° C.

8. The method of claim 7, wherein the first temperature is selected from the range of 500° C. to 1200° C.

9. The method of claim 5, wherein the dielectric material comprises at least one of SiO₂ and Si-rich silicon oxide and the second temperature is selected from a range of 300° C. to 1300° C.

10. The method of claim 9, wherein the second temperature is selected from a range of 400° C. to 1250° C.

11. The method of claim 10, wherein the second temperature is selected from a range of 500° C. to 1200° C.

12. The method of claim 1, wherein a thickness of the film is selected from a range of 0.1 μm to 5 μm.
